(19) United States
(12) Patent Application Publication
(10) Pub. No.: US 2005/0127045 A1
(43) Pub. Date: Jun. 16, 2005

(54) Laser crystallization apparatus and laser crystallization method

(75) Inventors: Nobuo Sasaki, Kawasaki (JP); Tatsuya Uzuka, Shinjuku (JP)

Correspondence Address: GREER, BURNS & CRAIN, 300 S WACKER DR, 25TH FLOOR, CHICAGO, IL, 60606, US

(73) Assignees: FUJITSU LIMITED; JAPAN LASER CORPORATION

(21) Appl. No.: 11/003,021

(22) Filed: Dec. 2, 2004

(30) Foreign Application Priority Data
Dec. 4, 2003 (JP) 2003-406167(PAT.)

(51) Int. Cl. B23K 26/00; H01L 21/00; H01L 21/84

(52) U.S. Cl. 219/121.6; 438/166

(57) ABSTRACT

The present invention relates to a laser crystallization apparatus and a laser crystallization method that can achieve high throughput even when a CW laser is used. The laser crystallization apparatus includes a movable stage supporting a substrate on which a semiconductor layer is formed, a device directing a laser beam to a plurality of optical paths in a time-division manner, and optical devices condensing and applying the laser beam passing through the optical paths to the semiconductor layer on the substrate supported by the stage. A first region of the semiconductor layer is scanned with the laser beam in one direction and a second region of the semiconductor layer is scanned with the laser beam in the reverse direction.

### BACKGROUND OF THE INVENTION

1. Field of the Invention

The present invention relates to a laser crystallization apparatus and a laser crystallization method.

2. Description of the Related Art

A liquid crystal display device includes an active matrix driving circuit including TFTs. Further, a system liquid crystal display device includes electronic circuits including TFTs in a peripheral region around a display region. Low-temperature Poly-Si is suitable for forming the TFTs in the liquid crystal display device and the TFTs in the peripheral region of the system liquid crystal display device. Further, the low-temperature Poly-Si is expected to be applied to pixel driving TFTs in an organic EL display or electronic circuits in a peripheral region of the organic EL display. The present invention relates to a semiconductor crystallization method and apparatus using a CW laser (continuous wave laser) for fabricating the TFTs from the low-temperature Poly-Si.

Conventionally, in order to form the TFTs of the liquid crystal display device from the low-temperature Poly-Si, an amorphous silicon film is formed on a glass substrate and the amorphous silicon film on the glass substrate is irradiated with excimer pulse laser to crystallize the amorphous silicon. Recently, a technique for crystallizing the amorphous silicon by irradiating the amorphous silicon film on the glass substrate with CW solid-state laser has been developed (for example, see Japanese Unexamined Patent Publication No. 2003-86505 and the Institute of Electronics, Information and Communication Engineers (IEICE) Transactions, Vol. J85-C No. 8, August 2002). The amorphous silicon is melted by a laser beam and then solidified, wherein the solidified portion turns into polysilicon.

While the mobility value in the silicon crystallization by the excimer pulse laser is about 150-300 (cm²/Vs), a mobility of about 400-600 (cm²/Vs) can be obtained in the silicon crystallization by the CW laser, which is advantageous in the formation of high-performance polysilicon.

In the silicon crystallization, an amorphous silicon film is scanned by a laser beam. In this case, a substrate having the silicon film is mounted on a movable stage so that the silicon film is scanned by moving the silicon film with respect to the fixed laser beam. In the case of the excimer pulse laser, for example, the scan operation can be performed by the laser beam having a beam spot of 27.5 cm×0.4 mm. On the other hand, in the case of the CW solid-state laser having a smaller beam spot, the laser beam is condensed as an elliptical spot by using an optical system such as a cylindrical lens. In this case, for example, the size of the beam spot is tens to hundreds of μm and the scanning operation is performed in a direction perpendicular to the major axis of the ellipse. Thus, the crystallization by the CW solid-state laser suffers from low throughput even though high-quality polysilicon can be obtained.

Because a CW laser has a small beam spot and, therefore, only a small area of amorphous silicon can be crystallized in one scan, a plurality of scans are performed successively to crystallize a required area of the amorphous silicon. In this case, a glass substrate is mounted on a movable stage and raster scanning is performed so that beam traces one scan in the forward direction and the next scan in the reverse direction to partially overlap each other. If the amount of overlap is small, a noncrystallized area may be formed between the two beam traces and therefore, the overlapping amount is determined with the addition of a positional tolerance. But, if the overlapping amount is large, the total width of the two beam traces is reduced and throughput is thus reduced.

In recent research, it has been found that the beam traces meander minutely. Though it can be said generally that the stage is moved linearly, the movement of the stage is in fact accompanied with minute meanderings even though the stage is controlled so that it is moved linearly and therefore, the beam trace crystallized in one scanning meanders as shown later. If there are meanderings, the overlapping amount between the two beam traces must be increased and as a result, the throughput is reduced.

Further, when a semiconductor layer in the peripheral region around the display region of the liquid crystal display device is crystallized, the scans must be performed in two directions orthogonal to each other. Therefore, the movable stage supporting the substrate on which the semiconductor layer is formed must be rotatable. The conventional rotary stage includes an XY stages and a rotary stage, wherein the substrate is attached to the rotary stage and the rotary stage can be rotated 90 degrees and, further, if it is rotated, the scannings can be performed in the two directions orthogonal to each other. However, the conventional rotary stage is provided also for the purpose of angular correction in final positioning of the substrate and, in this case, it must operate with high precision and accuracy of 0.1-0.2 seconds in the rotation range of several degrees. In order to achieve such precision, the conventional rotary stage is not designed to be rotated 90 degrees. Therefore, the stage must be redesigned as a whole so that the rotary stage can be rotated 90 degrees. Further, even when the rotary stage is manufactured so that it can be rotated 90 degrees, it must be designed to operate precisely for the final positioning of the substrate and therefore, the cost of the rotary stage will be high. As a result, when the scans are performed in two directions orthogonal to each other, an operator must pick up the substrate, turn it 90 degrees and reset it on the rotary stage by hand and, therefore, the operation becomes troublesome and the throughput is reduced.

### SUMMARY OF THE INVENTION

It is an object of the present invention to provide a laser crystallization apparatus and a laser crystallization method that can achieve high throughput even when a CW laser is used.

A laser crystallization apparatus, according to the present invention, comprises a movable stage supporting a substrate having a semiconductor layer formed thereon, a device directing a laser beam to a plurality of optical paths in a time-division manner, and optical devices condensing and applying the laser beam passing through the optical paths to the semiconductor layer on the substrate supported by the stage.

Further, a laser crystallization method, according to the present invention, comprises the steps of directing a CW laser beam to at least two optical systems in a time-division manner, crystallizing a first region of a semiconductor layer formed on a substrate by using one of the optical systems to which the laser beam is directed, and crystallizing a second region of the semiconductor layer formed on the substrate that is spaced from the first region by using another of the optical systems to which the laser beam is directed.

In the laser crystallization apparatus and the laser crystallization method described above, the CW laser beam is directed to at least two optical systems in a time-division manner and different regions of the semiconductor layer are crystallized successively by using the respective optical systems. Therefore, a beam trace formed by the scan in one direction and another beam trace formed in the scan in the reverse direction do not overlap each other and it is possible to arrange such that only the beam traces formed in the scans in one specific direction overlap each other. As a result, the amount of overlap can be determined with a lower estimate of an effect of meandering in the beam traces resulted from the stage. Thus, a high throughput can be achieved even when a CW laser is used.

Also, a laser crystallization apparatus, according to the present invention, comprises a movable stage supporting a substrate having a semiconductor layer formed thereon, an optical device for applying a laser beam to the semiconductor layer on the substrate supported by the stage, a rotary device that is provided separately from the stage and can rotate the substrate, and a transporting device that can transport the substrate at least between the stage and the rotary device.

In this configuration in which the rotary device is provided separately from a rotary stage on XY stages, when scans are performed in two directions orthogonal to each other, first, a scan is performed in one direction while supporting the substrate having the semiconductor layer formed thereon, then the substrate is transported from the stage to the rotary device to rotate the substrate by 90 degrees and then, the substrate is transported from the rotary device to the stage to support the substrate on the stage to perform another scan in another direction. Thus, the scans can be performed successively in the two directions orthogonal to each other. Therefore, while the conventional stage with a limited rotation range but with high precision is used as it is, the scans can be performed without reduction of throughput by only newly providing the rotary stage that can be rotated 90 degrees. In this case, it is only required that the rotary device can be rotated 90 degrees or 90 plus some degrees but it does not have to provide high-precision and an accuracy of 0.1-1 degrees suffices (the precision is ensured by the rotary stage on the XY stages).

As described above, according to the present invention, throughput can be improved significantly because both forward and backward scans can be used for crystallization and, even if there are meanderings, the crystallization can be achieved only by either the forward or the backward scans in each crystallization region and therefore, the scanning pitch can be increased. Further, the present invention improves throughput of low-temperature polysilicon TFTs through crystallization by CW laser and as a result, contributes to development of devices including high-performance TFTs resulting from the low-temperature polysilicon technology, such as sheet computers, intelligent FPDs and low-cost CMOS.

### BRIEF DESCRIPTION OF THE DRAWINGS

FIG. 1 is a schematic cross-sectional view showing a liquid crystal display device manufactured according to the present invention;

FIG. 2 is a schematic plan view showing the TFT substrate of FIG. 1;

FIG. 3 is a schematic plan view showing a mother glass for fabricating the TFT substrate of FIG. 2;

FIG. 4 is a schematic plan view showing a laser crystallization apparatus according to an embodiment of the present invention;

FIG. 5 is a perspective view showing the laser crystallization apparatus of FIG. 4;

FIG. 6 is a side view showing the configuration of the optical device of FIGS. 4 and 5;

FIG. 7 is a plan view showing an example of the device directing a laser beam to a plurality of optical paths in a time-division manner, of FIGS. 4 and 5;

FIG. 8 is a perspective view showing a substrate supported by the stage;

FIG. 9 is a diagram showing an example of overlapping beam traces;

FIG. 10 is a diagram showing an example of a meandering beam trace;

FIG. 11 is a diagram showing an example of overlapping beam traces when the scanning according to the present invention is performed;

FIG. 12 is a diagram showing an example of overlapping beam traces when the reciprocating scanning is performed;

FIG. 13 is a side view showing a laser crystallization apparatus according to another embodiment of the present invention;

FIG. 14 is a perspective view showing an example of the stage;

FIG. 15 is a perspective view showing an example of the transporting device of FIG. 13; and

FIG. 16 is a schematic plan view showing a variation of the laser crystallization apparatus.

### DESCRIPTION OF THE PREFERRED EMBODIMENTS

Preferred embodiments of the present invention will now be described with reference to the drawings.

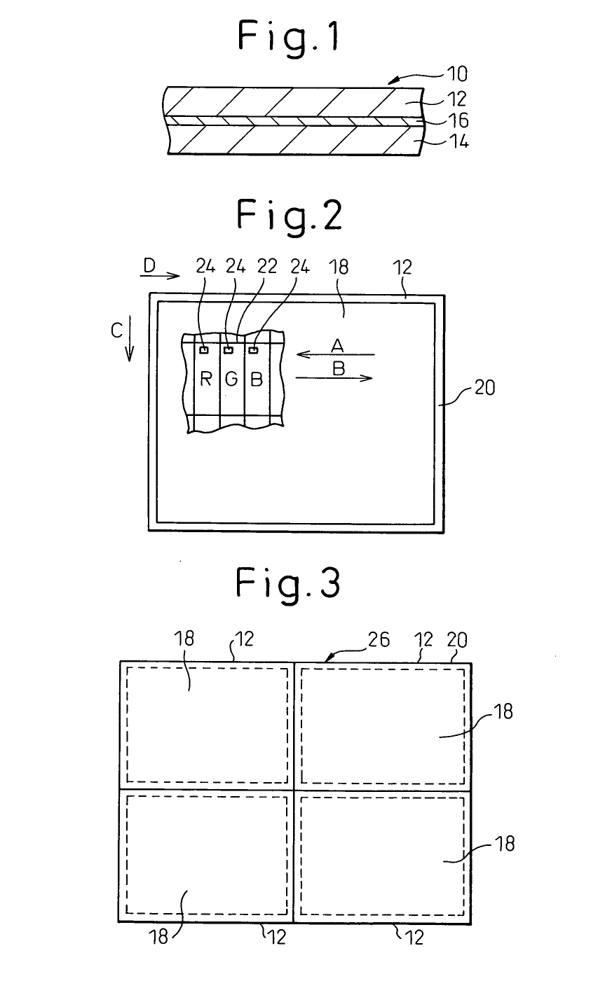

FIG. 1 is a schematic cross-sectional view showing a liquid crystal display device according to an embodiment of the present invention. The liquid crystal display device 10 comprises a pair of opposing glass substrates 12 and 14, and a liquid crystal 16 inserted therebetween. The glass substrates 12 and 14 can be provided with electrodes and alignment films. One of the glass substrates 12 is a TFT substrate and the other of the glass substrates 14 is a color filter substrate.

FIG. 2 is a schematic plan view showing the glass substrate 12 of FIG. 1. The glass substrate 12 has a display region 18 and a peripheral region 20 around the display region 18. The display region 18 includes a large number of pixels 22. In FIG. 2, one of the pixels 22 is shown in a partly enlarged manner. The pixel 22 includes sub-pixel regions of three primary colors RGB and TFTs 24 are formed in respective sub-pixel regions of three primary colors. The peripheral region 20 has TFTs (not shown), wherein the TFTs in the peripheral region 20 are arranged more densely than the TFTs 24 in the display region 18.

The glass substrate 12 of FIG. 2 constitutes a 15 inch QXGA liquid crystal display device having 2048×1536 pixels 22. In the direction (horizontal direction) in which the sub-pixel regions RGB of the three primary colors are aligned, 2048 pixels are aligned and, therefore, the number of the sub-pixel regions RGB is 2048×3. In the direction (vertical direction) perpendicular to that in which the sub-pixel regions RGB of the three primary colors are aligned (horizontal direction), 1536 pixels are aligned. In the semiconductor crystallization process, in the peripheral region 20, the laser scanning is performed in the directions parallel to the sides thereof, whereas, in the display region 18, the laser scanning is performed in the direction A or B.

FIG. 3 is a schematic plan view showing a mother glass 26 for fabricating the glass substrate 12 of FIG. 2. The mother glass 26 is configured so that a plurality of the glass substrates 12 can be obtained therefrom. Though four glass substrates 12 are obtained from one mother glass 26 in the example shown in FIG. 3, more than four glass substrates 12 may be obtained.

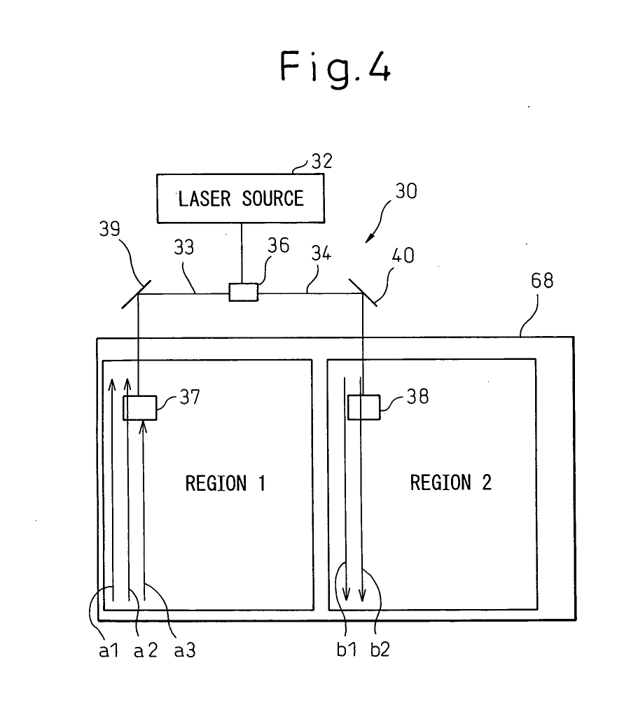

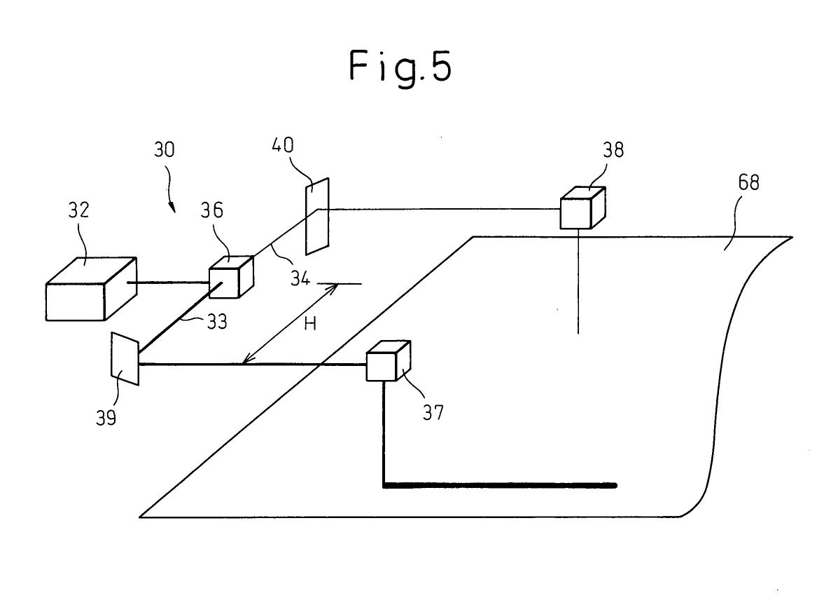

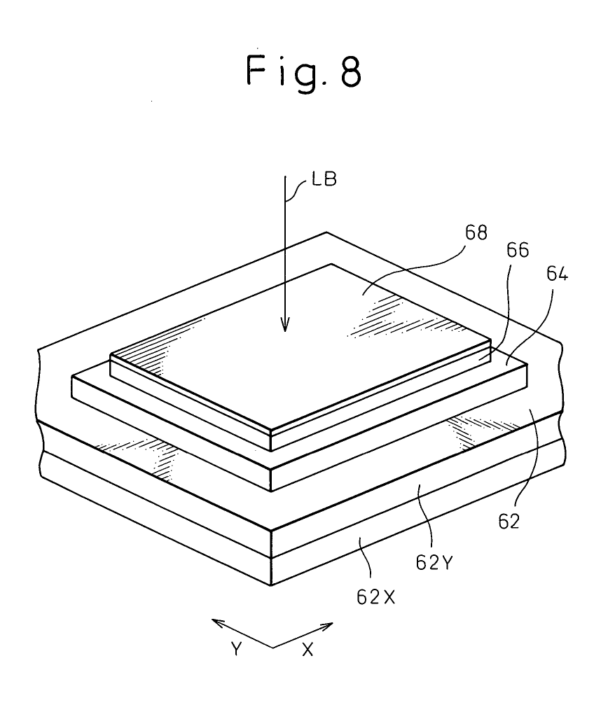

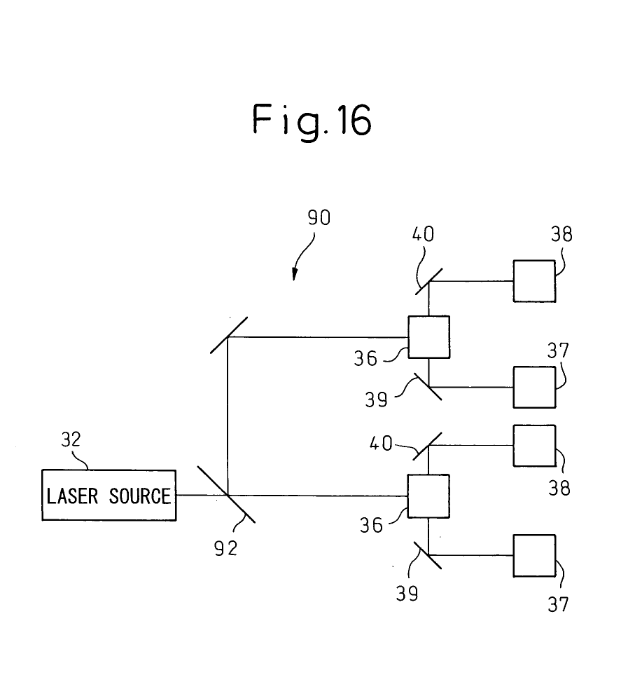

FIG. 4 is a schematic plan view showing a laser crystallization apparatus according to an embodiment of the present invention. FIG. 5 is a perspective view showing the laser crystallization apparatus of FIG. 4. The laser crystallization apparatus 30 comprises a movable stage 62 supporting a substrate 66 having a semiconductor layer (an amorphous silicon film) 68 formed thereon (FIG. 8), a laser source 32, a device 36 directing the laser beam emitted from the laser source 32 to a plurality of optical paths 33 and 34 in a time-division manner, and optical devices 37 and 38 condensing and applying the laser beam passing through the optical paths 33 and 34 onto the semiconductor layer 68 on the substrate 66 supported by the stage 62. The laser beam input to the device 36 may not only come directly from the laser source 32 but, for example, it may be one of sub-beams divided simultaneously by a half mirror as shown in FIG. 16. Further, inversely, outgoing light from the device 36 may be divided simultaneously into sub-beams.

The laser source 32 includes a CW laser (continuous wave laser) oscillator. The semiconductor layer 68 includes a region 1 and a region 2. The semiconductor layer 68 does not have to be divided into the region 1 and the region 2 particularly but, here, it is merely so divided for convenience of description. In the shown embodiment, the optical paths 33 and 34 divided at the device 36 are oriented in opposite directions and mirrors 39 and 40 reflect the optical paths 33 and 34, respectively, so that they are parallel to each other. The distance H between the center of the device 36 and the mirror 39 (40) can be changed so that the distance between the mirrors 39 and 40 or, in other words, the distance between the optical devices 37 and 38 can be adjusted. It is preferable that the mirror 39 and the optical device 37 are integrally supported by a first supporting means and the mirror 40 and the optical device 38 are integrally supported by a second supporting means so that the relative position between the first supporting means and the second supporting means can be changed by a single axis stage.

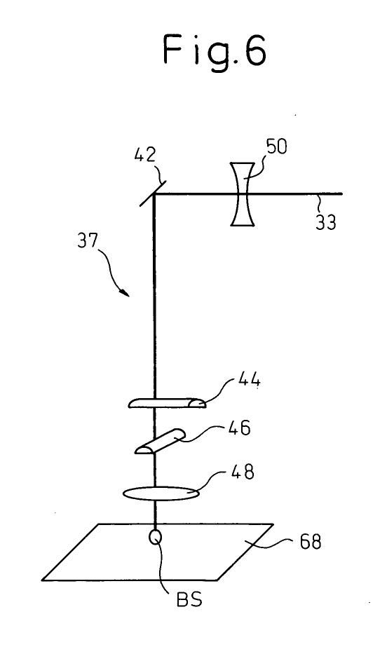

FIG. 6 is a side view showing the configuration of the optical device 37 of FIGS. 4 and 5. Though FIG. 6 shows the configuration of the optical device 37 of FIG. 5, it is to be understood that the optical device 38 is also configured similarly. The optical device 37 comprises a mirror 42 that reflects the optical path of the laser beam from the horizontal direction to the vertical direction, a cylindrical lens 44 that is formed substantially as a semicylinder, a cylindrical lens 46 that is disposed orthogonal to the cylindrical lens 44 and formed substantially as a semicylinder, and a convex lens 48. The mirror is preferably formed of a total reflection dielectric multilayer film. This optical device 37 (38) makes a beam spot BS of the laser beam elliptical on the semiconductor layer 68. Further, a concave lens 50 is preferably disposed on the upstream side of the mirror 42. However, the optical device 37 (38) does not have to include all these elements.

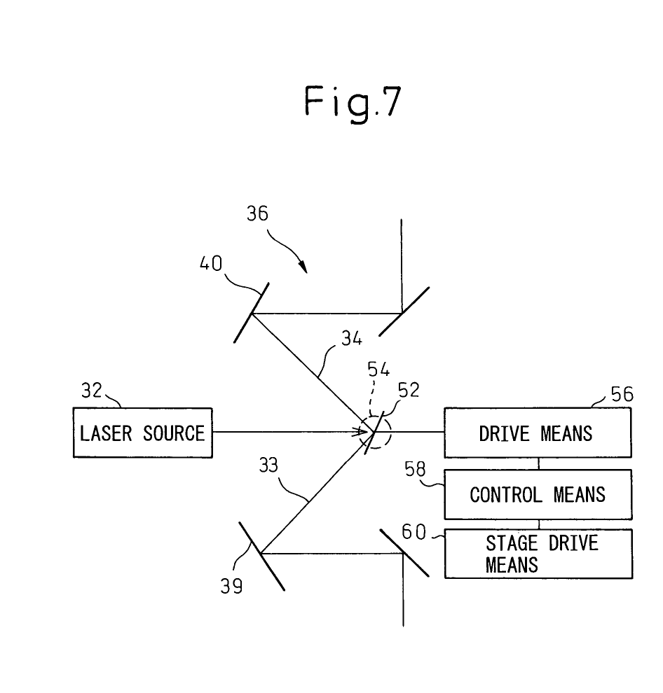

FIG. 7 is a plan view showing an example of the device 36 of FIGS. 4 and 5 that directs the laser beam to the optical paths 33 and 34 in a time-division manner. The device 36 includes a galvanometer mirror 52. The galvanometer mirror 52 is a mirror driven by a motor 54 and the motor 54 is connected to a control means 58 via a drive means (driving circuit) 56. A stage drive means (driving circuit) 60 is also connected to the control means 58. The control means 58 controls the galvanometer mirror 52 and the stage 62 to operate them in synchronization with each other. The galvanometer mirror 52 may be substituted by a polygon mirror.

The laser beam reflected by the galvanometer mirror 52 is directed to the mirror 39 or 40 depending on the position of the galvanometer mirror 52. The galvanometer mirror 52 is driven so that the laser beam is directed along the optical path 33 or 34 alternately. In FIG. 7, the galvanometer mirror 52 is positioned so that the laser beam is reflected toward the mirror 40, wherein the light emitted from the laser source 32 is reflected by the galvanometer mirror 52 to enter the optical path 34 and, then, is reflected by the mirror 40 to the mirror 42 in the optical device 37 of FIG. 6. At the next point in time, the galvanometer mirror 52 is displaced to the position to direct the laser beam to the mirror 39, wherein the light emitted from the laser source 32 is reflected by the galvanometer mirror 52 to enter the optical path 33 and, then, reflected by the mirror 39 to the mirror 42 in the optical device 38. In this connection, FIGS. 4 and 5 show the optical paths 33 and 34 oriented to the opposite directions in a straight line, whereas FIG. 7 shows the optical paths 33 and 34 oriented to the opposite directions at an angle. The important thing is that the laser beams, reflected by the mirrors 39 and 40 respectively, are parallel to each other.

FIG. 8 is a perspective view showing the substrate 66 supported by the stage 62. The stage 62 includes an X stage 62X, a Y stage 62Y and a rotary stage (not shown in FIG. 8). The X stage 62X is disposed on a guide (not shown) so that the X stage 62X can be moved in the X direction and it is driven in the X direction by a driving means such as a feed screw (not shown). The Y stage 62Y is disposed on a guide (not shown), which is, in turn, provided on the X stage 62X, so that the Y stage 62Y is driven in the Y direction by a driving means such as a feed screw (not shown). The rotary stage is rotatably disposed on the Y stage 62Y and rotatably driven by a driving means (not shown).

A suction table 64 is mounted on the rotary stage on the Y stage 62Y. The suction table 64 forms a vacuum suction chuck having a plurality of vacuum suction holes and vacuum passages. The substrate 66 is, for example, the mother glass 26 shown in FIG. 3 and the semiconductor layer 68 consisting of amorphous silicon is formed on the substrate 66 by a thin film manufacturing process. A laser beam LB is condensed and applied by the optical device 37 (38) shown in FIG. 6 to the semiconductor layer 68.

Scanning is performed in the state in which the laser beam LB illuminates a fixed position while the stage 62 is moved, so a strip-like portion of the semiconductor layer 68 is illuminated by the laser beam LB. A portion of the semiconductor layer 68 of amorphous silicon illuminated by the laser beam is melted, solidified and crystallized to turn into polysilicon. Within the strip-like portion illuminated by the laser beam in the semiconductor layer 68, there is an effective melt width where the semiconductor layer 68 is melted sufficiently, but its opposite side portions are not melted sufficiently. Here, the portion of the semiconductor layer 68 included in the effective melt width is referred to as a beam trace.

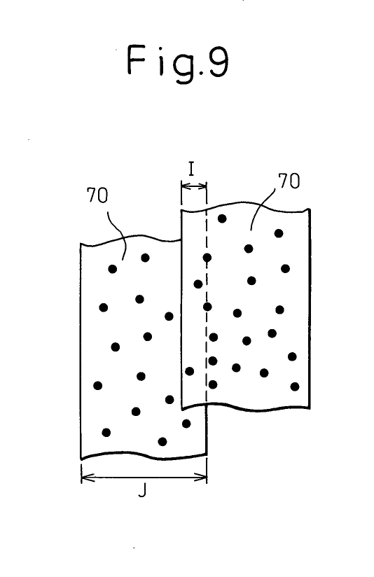

FIG. 9 is a diagram showing an example of overlapping beam traces. Two beam traces 70 overlap each other with the overlapping amount of “I”. “J” indicates an effective melt width. Because the CW laser has a small beam spot and, therefore, only a small area of the semiconductor layer 68 can be crystallized in one scan, so a plurality of scans are performed successively allowing the beam traces to overlap each other so that a required area of the semiconductor layer 68 is crystallized.

In this case, as shown in FIG. 4, raster scanning is performed. In raster scanning, the Y stage 62Y is moved in one direction (the forward direction) along the Y axis, the X stage 62X is then moved in the direction along the X axis and the Y stage 62Y is then moved in the reverse direction (the backward direction) along the Y axis. While the region 1 of the semiconductor layer 68 is crystallized in the scanning in the one direction (the forward direction), the region 2 of the semiconductor layer 68 is crystallized in the scanning in the opposite direction (the backward direction).

In FIG. 4, the first scanning is performed as shown by arrow al in the region 1 of the semiconductor layer 68. The second scanning is performed as shown by arrow b1 in the region 2 of the semiconductor layer 68. The third scanning is performed as shown by arrow a2 in the region 1 of the semiconductor layer 68. The fourth scanning is performed as shown by arrow b2 in the region 2 of the semiconductor layer 68. As described above, by repeating the scanning in the opposite directions alternately, the portion required to be crystallized in the semiconductor layer 68 is crystallized.

The control means 58 controls the galvanometer mirror 52 and the stage 62 to operate them in synchronization with each other. In the forward scannings a1, a2 and a3, the device 36 operates so that the laser beam passes through the optical path 33 whereas, in the backward scannings b1 and b2, the device 36 operates so that the laser beam passes through the optical path 34.

Regarding the forward scannings, the beam trace formed in the semiconductor layer 68 when the stage 62 (62Y) is moved in the one direction al and the beam trace formed in the semiconductor layer 68 when the stage 62 (62Y) is next moved in the same direction a2 overlap each other. Regarding the backward scannings, the beam trace formed in the semiconductor layer 68 when the stage 62 (62Y) is moved in the reverse direction b1 and the beam trace formed in the semiconductor layer 68 when the stage 62 (62Y) is next moved in the same direction b2 overlap each other. Thus, the two beam traces 70 shown in FIG. 9 represent the beam traces in the region 1 (region 2).

In this way, the present invention includes a mechanism for switching the laser beam between the different optical systems alternately in synchronization with the forward and backward scannings, in which these optical systems comprise optical focusing systems for illuminating the regions different from each other, and a function for scanning the condensed beam traces in an overlapping manner.

On the other hand, regarding the successive forward and backward scannings, the beam trace formed in the semiconductor layer 68 when the stage 62 (62Y) is moved in the one direction al and the beam trace formed in the semiconductor layer 68 when the stage 62 (62Y) is next moved in the reverse direction b1 opposite are spaced from each other.

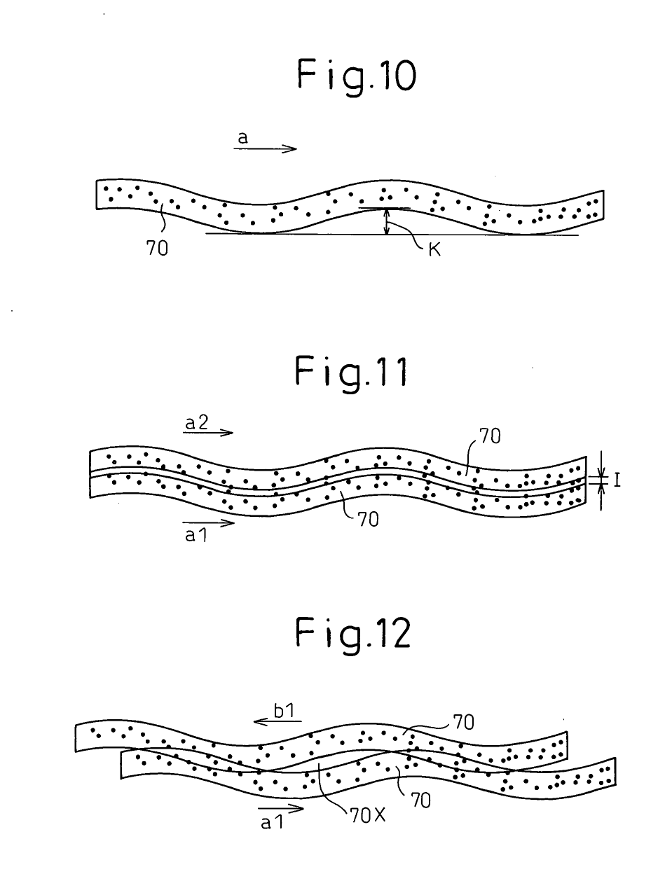

FIG. 10 is a diagram showing an example of a meandering beam trace. “K” indicates the amount of meandering. In the recent research, it has been found that the beam trace 70 minutely meanders. That is, the stage 62 (62Y) is moved linearly, in general, but the movement of the stage 62 (62Y) is in fact accompanied with meandering even though the stage is controlled so that it is moved linearly and, therefore, the beam trace 70 crystallized in one scanning meanders, as shown in FIG. 10.

FIG. 11 is a diagram showing an example of overlapping beam traces when the scanning is performed according to the present invention. For example, FIG. 11 shows a beam trace 70 when the stage 62 (62Y) is moved in the one direction al in FIG. 4 and another beam trace 70 when the stage 62 (62Y) is next moved in the same direction a2 in FIG. 4, wherein these two beam traces overlap each other with the overlapping amount “I”. In the case of scanning in the same direction, the meanderings are in phase and, therefore, it is possible to reduce the overlapping amount.

FIG. 12 is a diagram showing an example of overlapping beam traces when the forward and backward scannings are performed. For example, FIG. 12 shows a beam trace 70 when the stage 62 (62Y) is moved in the one direction al and another beam trace 70 when the stage 62 (62Y) is moved in the reverse direction b1, with these beam traces being brought closer to each other so that they overlap each other. In this case, because of meanderings in the both beam traces 70 that may occur independently of each other, if the amount of overlap is small, a noncrystallized area 70X may be formed between the two beam traces 70. Thus, if there are meanderings, the overlapping amount between the two beam traces 70 must be increased and, as a result, throughput is reduced.

In the preferred embodiment, an amorphous silicon film is crystallized by CW laser irradiation. A CW laser beam of 532 nm wavelength is obtained by using a DPSS laser of Nd: YVO4 and its harmonics (multiple waves). For example, using an elliptical beam spot, an amorphous silicon film having a thickness of about 100 nm is scanned at a laser power of 2.5 W and a laser scan speed of 2 m/s. As shown in FIG. 10, in one laser trace 70, the effective melt width “J” is 20 μm and the amount of meandering “K” is 5 μm.

In the reciprocating scanning shown in FIG. 12, the overlapping amount “I” of about 10 μm, which is the sum of the amount of meandering “K” and a positioning tolerance of about 5 μm, is required. Assuming a case in which the overlapping amount “I” can be reduced to 0 in an ideal condition with no meandering and no positioning tolerance, throughput in the reciprocating scanning shown in FIG. 12 is reduced to (20−10)/20=0.50 with respect to that in the ideal case.

In contrast to this, in the scanning shown in FIG. 11 to which the present invention is applied, it is possible to effectively use the forward and backward scanning for crystallization and one directional scanning can be applied without including the amount of meandering “K”, throughput in the scanning shown in FIG. 11 is improved to (20−5)/20=¾=0.75 with respect to that in the ideal case in which the overlapping amount “I” can be reduced to 0.

When laser power is limited or the thickness of the amorphous silicon film is large, the melt width is reduced. If the melt width is 15 μm, the throughput of the reciprocating scanning is (15−10)/15=⅓=0.33 with respect to that in the ideal case, but the throughput of the scannings according to the present invention is (15−5)/15=⅔=0.66.

When the raster scanning is not performed but the one directional scanning only, in either the forward or backward direction, is performed, the meanderings in the beam traces of a plurality of scannings are in phase as shown in FIG. 11 and, therefore, the overlapping amount of only 5 μm corresponding to the positional tolerance mentioned above is sufficient, even though the width of meandering is 5 μm. Therefore, the overlapping amount can be reduced as shown in FIG. 11. However, in the one directional scanning only in the forward direction, (or in the one directional scannings only in the backward direction) the forward beam traces can be used for crystallization but, during the backward movement, the laser beam must be blocked by a shutter, which means that the half of the scanning time is wasted and, as a result, the throughput is reduced.

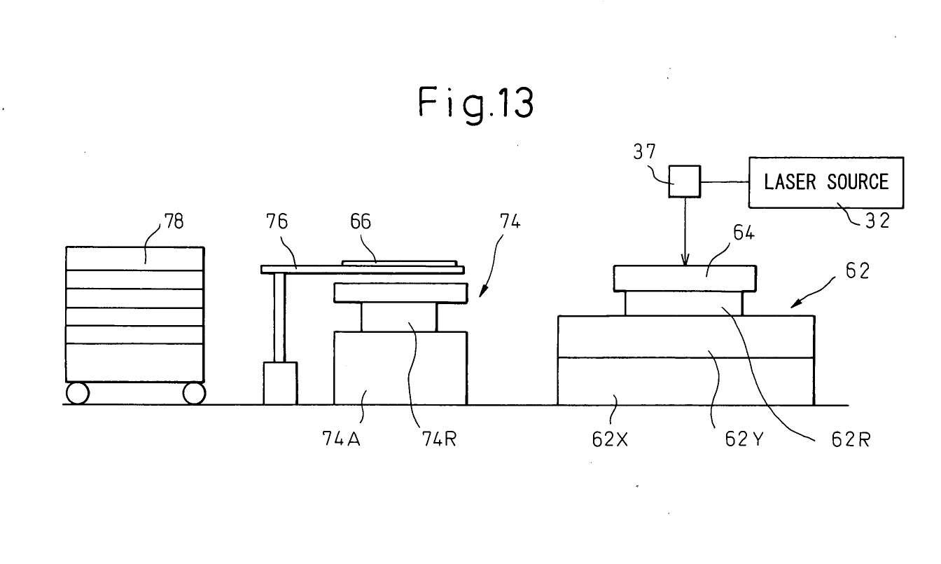

FIG. 13 is a side view showing a laser crystallization apparatus according to another embodiment of the present invention. The laser crystallization apparatus 72 of this embodiment comprises a movable stage 62 supporting a substrate 66 having a semiconductor layer 68 formed thereon (see FIG. 8), a laser source 32, an optical device 37 for applying a laser beam emitted from the laser source 32 to the semiconductor layer 68 on the substrate 66 supported by the stage 62, a rotary device 74 that is provided separately from the stage 62 and that can rotate the substrate 66, and a transporting device 76 that can transport the substrate 66 at least between the stage 62 and the rotary device 74. Further, there is provided a substrate stacker (holder) 78 formed as a transporting cart and the transporting device 76 can transport the substrate 66 between the stage 62 and the substrate stacker (holder) 78.

The stage 62 includes an X stage 62X, a Y stage 62Y and a rotary stage 62R. The X stage 62X is disposed on a guide (not shown) so that the X stage 62X can be moved in the X direction and it is driven in the X direction by a driving means such as a feed screw (not shown). The Y stage 62Y is disposed on a guide (not shown), which is, in turn provided on the X stage 62X, so that the Y stage 62Y is driven in the Y direction by a driving means such as a feed screw (not shown). The rotary stage 62R is rotatably disposed on the Y stage 62Y and rotatably driven by a driving means (not shown). A suction table 64 (see FIG. 8) is provided on the rotary stage 62R.

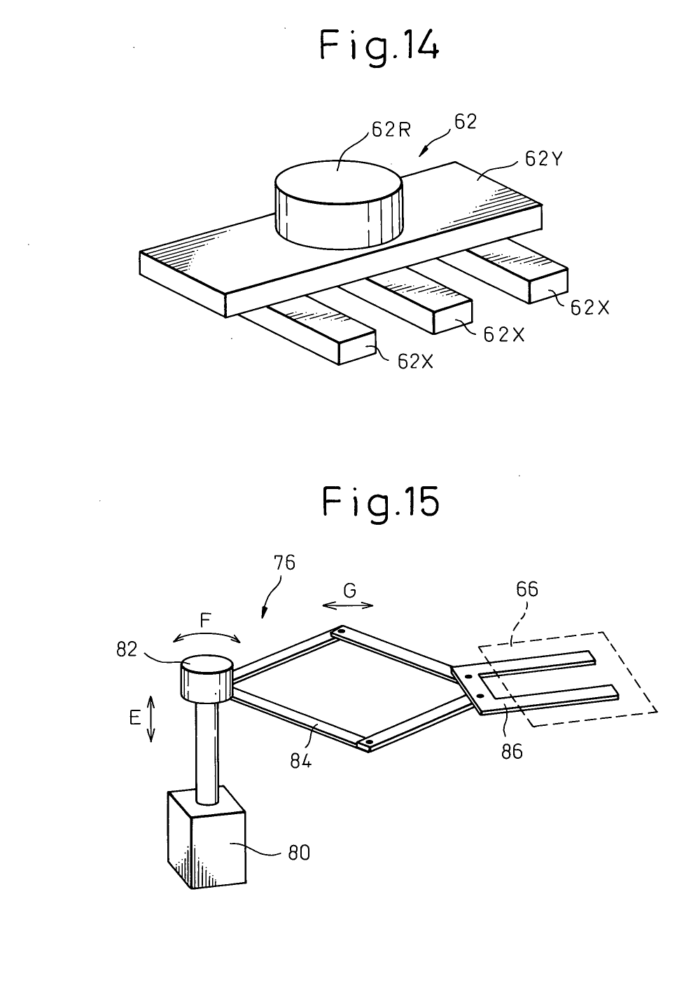

FIG. 14 is a perspective view showing an example of the stage 62. The X stage 62X comprising a plurality of split plates operates at low speed and has high position resolution. The Y stage 62Y comprising one long plate operates at high speed and has relatively low position resolution.

The rotary stage 62R is made to operate precisely in the rotation range of several degrees. That is, because the transporting device 76 takes out the substrate 66 from the substrate stacker 78 in a predetermined posture and puts it on the stage 62 in the predetermined posture, there is no particular need to rotate the substrate 66 on the stage 62 in this operational range. The rotary stage 62R is provided for fine adjustment of the position of the substrate 66.

On the other hand, as shown in FIG. 2, when the semiconductor layer 68 is crystallized in the preripheral region 20 around the display region 18 of the liquid crystal display device, the scanning must be performed in two directions (in the C and D directions) orthogonal to each other. Therefore, the substrate 66 must be rotated by 90 degrees. In this case, if the rotary device 74 is not provided, the substrate 66 should be manually rotated and put on the rotary table 62R. Otherwise, the rotary table 62R must be designed so that it can be rotated 90 degrees or more but manufacturing costs will be increased significantly if the rotary stage 62R is fabricated so that it can be rotated 90 degrees or more while having high resolution.

The rotary device 74 comprises a rotary stage 74R rotatably mounted on a stationary base 74A and further includes a driving means for rotating the rotary stage 74R. A vacuum suction chuck is provided on the rotary stage 74R. The rotary stage 74R can be rotated 90 degrees or more. It is not required that the rotary stage 74R can perform positioning operation with high accuracy.

FIG. 15 is a perspective view showing an example of the transporting device 76 of FIG. 13. The transporting device 76 is constructed as a robot comprising a base 80, a body 82 that can be moved in a vertical direction as shown by arrow E and rotated as shown by arrow F, a parallelogram link 84 attached to the body 82, and a fork-like arm 86. The parallelogram link 84 is extendable and retractable as shown by arrow G. The substrate 66 is transported while it is put on the arm 86. The rotary stage 62R of the stage 62 and the rotary stage 74R of the rotary device 74 have respective lifting pins (not shown) so that the arm 86 can be inserted between the substrate 66 and either the rotary stage 62R or the rotary stage 74R.

In FIG. 13, the transporting device 76 takes out the substrate 66 in a predetermined posture and puts it on the stage 62 in the predetermined posture. The rotary stage 62R of the stage 62 finely adjusts the position of the substrate 66, and the semiconductor layer 68 is crystallized, for example, along one side of the peripheral region 20 in the direction of arrow C. Then, the transporting device 76 transports the substrate 66 from the rotary stage 62R of the stage 62 to the rotary stage 74R of the rotary device 74. The rotary stage 74R is rotated with the substrate 66 by 90 degrees and, the transporting device 76 then transports the substrate 66 rotated by 90 degrees from the rotary stage 74R of the rotary device 74 to the rotary stage 62R of the stage 62. The rotary stage 62R of the stage 62 finely adjusts the position of the substrate 66, and the semiconductor layer 68 is crystallized, for example, along another side of the peripheral region 20 in the direction of arrow D. In this manner, the semiconductor layer can be crystallized with high throughput by providing the rotary device 74 of a simple construction.

FIG. 16 is a schematic plan view showing a variation of the laser crystallization apparatus. The laser crystallization apparatus 90 has a beam splitting means 92 such as a half mirror for splitting a laser beam emitted from the laser source 32 into two sub-beams. For each of the sub-beams divided by the beam splitting means 92, the laser crystallization apparatus 90 comprises the device 36 shown in FIGS. 4 and 5 that directs the laser beam to a plurality of optical paths 33 and 34 in a time-division manner and optical devices 37 and 38 condensing and applying the laser beams passing through the optical paths 33 and 34 to the semiconductor layer 68 on the substrate supported on the stage 62. Thus, the area of the semiconductor layer 68 crystallized simultaneously can be increased.

1. A laser crystallization apparatus comprising:
a movable stage supporting a substrate having semiconductor layer formed thereon;
a device directing a laser beam to a plurality of optical paths in a time-division manner; and
optical devices condensing and applying the laser beam passing through said respective optical paths to said semiconductor layer on said substrate supported by said stage.

2. The laser crystallization apparatus according to claim 1, further comprising control means for controlling said device for directing the laser beam to the optical paths in a time-division manner and said stage to which said substrate is attached in synchronization.

3. The laser crystallization apparatus according to claim 2, wherein said control means controls said device for directing the laser beam to the optical paths in a time-division manner and said stage so that a beam trace formed on said semiconductor layer when said stage is moved in one direction and another beam trace formed in said semiconductor layer when said stage is moved in said one direction overlap each other.

4. The laser crystallization apparatus according to claim 1, wherein said device directing the laser beam to the optical paths in a time-division manner comprises a movable mirror.

5. The laser crystallization apparatus according to claim 4, wherein said movable mirror comprises a galvanometer mirror.

6. The laser crystallization apparatus according to claim 1, wherein said optical device comprises a stationary mirror and at least one condensing lens.

7. The laser crystallization apparatus according to claim 6, wherein stationary mirrors of said optical devices are arranged such that the laser beam reflected by one of said stationary mirrors is parallel to the laser beam reflected by another of said stationary mirrors.

8. The laser crystallization apparatus according to claim 1, further comprising a laser source delivering a laser beam to said device directing the laser beam to the optical paths in a time-division manner.

9. The laser crystallization apparatus according to claim 8, wherein said laser source comprises a CW laser oscillator.

10. The laser crystallization apparatus according to claim 9, wherein said laser source directly delivers the laser beam to said device.

11. The laser crystallization apparatus according to claim 9, further comprising a beam splitter between said laser source and said device.

12. The laser crystallization apparatus according to claim 1, wherein said substrate is one from which a plurality of glass substrates for liquid crystal display devices are acquired.

13. A laser crystallization method comprising the steps of:
directing a CW laser beam to at least two optical systems in a time-division manner;
crystallizing a first region of a semiconductor layer formed on a substrate by using one of said optical systems to which the laser beam is directed; and
crystallizing a second region of said semiconductor layer formed on said substrate that is spaced from said first region by using another of said optical systems to which the laser beam is directed.

14. The laser crystallization method according to claim 13, further comprising the steps of:
moving a stage supporting a substrate having said semiconductor layer formed thereon in one direction while the first region of the semiconductor layer is crystallized; and
moving said stage in the direction reverse to said one direction while the second region of the semiconductor layer is crystallized.

15. The laser crystallization method according to claim 14, wherein said substrate is one from which a plurality of glass substrates for liquid crystal display devices are acquired and each glass substrate with the semiconductor has a display region and a peripheral region around the display region, said first region corresponding to the display region of one of said glass substrate, said second region corresponding to the display region of another of said glass substrate.

16. The laser crystallization method according to claim 15, further comprising the step of:
crystallizing a portion of said semiconductor layer corresponding to said peripheral region.

17. A laser crystallization apparatus comprising:
a movable stage supporting a substrate having a semiconductor layer formed thereon;
an optical device for applying a laser beam to said semiconductor layer on said substrate supported by said stage;
a rotary device that is provided separately from said stage and can rotate said substrate; and
a transporting device that can transport said substrate at least between said stage and said rotary device.

18. The laser crystallization apparatus according to claim 17, wherein said stage comprises an X stage, a Y stage provided on the X stage, and a rotary stage provided on the Y stage;
wherein said rotary device comprises a base and a rotary stage provided on said base and rotatable by 90 degrees or more, said rotary stage of said movable stage being rotatable by an angle smaller the rotatable angle of said rotary stage of said rotary device; and
wherein said transporting device can transport the substrate between the rotary stage of the movable stage and the rotary stage of the rotary device in a constant posture.

19. The laser crystallization apparatus according to claim 18, wherein said rotary stage of said movable stage is rotatable by an angle smaller than 10 degrees.
